(19) United States
(12) Patent Application Publication
(10) Pub. No.: US 2005/0248010 A1
(43) Pub. Date: Nov. 10, 2005

(54) Semiconductor package and system module

(75) Inventors: Takao Ono, Tokyo (JP); Tomohiko Sato, Tokyo (JP); Hironori Iwasaki, Tokyo (JP)

Correspondence Address: SUGHRUE MION, PLLC, 2100 PENNSYLVANIA AVENUE, N.W., SUITE 800, WASHINGTON, DC, 20037, US

(73) Assignees: ELPIDA MEMORY, INC, Renesas Eastern (JP); Semiconductor, Inc., Renesas Technology Corp

(21) Appl. No.: 11/080,545

(22) Filed: Mar. 16, 2005

(30) Foreign Application Priority Data
Mar. 16, 2004 (JP) 2004-73728

(51) Int. Cl. H01L 23/02

(52) U.S. Cl. 257/678

(57) ABSTRACT

A thermal expansion coefficient of a module substrate 8 is different from that of a package substrate. There is not any place where stresses generated in Interfaces between soldering balls 5 and the substrate are released. These stresses are largely applied to soldering bond, the soldering balls are strained, deformed, or cracked, and there has been a problem in long-time reliability. Slits are disposed on opposite sides of each soldering ball in a vertical direction to a side in an outer peripheral side of the package substrate, accordingly the stresses applied to the soldering balls are weakened, and the soldering balls are prevented from being strained, deformed, or cracked. When soldering strains are reduced in this manner, there can be provided a surface mounting type semiconductor package and system module having high reliability, low cost, and satisfactory electric characteristics such as low capacitance and low inductance.

This application claims priority to prior Japanese patent application JP 2004-73728, the disclosure of which is incorporated herein by reference.

### BACKGROUND OF THE INVENTION

(1) Field of the Invention

The present invention relates to a semiconductor package and a system module, particularly to a semiconductor package and a system module comprising soldering balls for surface mounting.

(2) Description of the Related Art

In recent years, there has been an increasing demand for speeding-up and miniaturization of a semiconductor device. To improve electric characteristics of a connection point in mounting the semiconductor device onto an apparatus module substrate, the device is directly soldered to the module substrate via soldering balls, and a surface mounting type semiconductor package, such as COB, μBGA, FBGA, or the like, which can be provided with low capacitance, inductance, and cost has been actively developed.

Furthermore, a stacked package has also been developed in which chips-on-boards (COBs) are stacked. The COB includes semiconductor chips mounted on a substrate. The substrate has soldering balls. The miniaturization of the stacked package has advanced.

Various techniques have heretofore been described in order to improve connection characteristics of the semiconductor package to the module substrate, for example, contact defect, short circuit between adjacent terminals, and contact resistance increase (e.g., slits are disposed in a metal-formed stiffener of a package, an adhesive void to which the stiffener and film carrier tape are attached is eliminated, and soldering deformation by void expansion at a soldering time is prevented (see Japanese Patent Application Laid-Open No. 11-251480). Slits are disposed in a package substrate, a slit sectional portion is formed into a wire cable path, and accordingly a contact area is increased to thereby eliminate connection defects (see Japanese Patent Application Laid-Open No. 10-321753). Furthermore, a technique is described in which grooves are disposed between lands of a package, and solder bridging between the lands is prevented (see Japanese Patent Application Laid-Open No. 07-122842)).

However, when a surface mounting type semiconductor package is mounted on an apparatus module substrate, the soldering balls are plastically deformed by thermal stress of a soldering high temperature process, and there has been a problem in connection reliability. In this case, a thermal expansion coefficient of the module substrate is different from that of the package substrate. There is not any place where stresses generated in interfaces between the soldering balls and the substrate are released. These stresses are largely applied to soldering bond, the soldering balls are deformed or cracked, and there has been a problem in long-time reliability.

### SUMMARY OF THE INVENTION

It is an object of the present invention to provide a small-sized surface mounting type semiconductor package whose soldering strains are reduced and which has high reliability, low cost, and satisfactory electric characteristics such as low capacitance and low inductance.

It is another object of the present invention to provide a small-sized surface mounting type system module whose soldering strains are reduced and which accordingly has high reliability, low cost, and satisfactory electric characteristics such as low capacitance and low inductance.

According to one aspect of the present invention, there is provided a semiconductor package which has a semiconductor chip mounted thereon. The semiconductor package comprises a substrate having an area on which the semiconductor chip is mounted and ball mounting regions extended from the predetermined area and a plurality of metal balls mounted on said ball mounting regions of the substrate. The ball mounting regions are spaced apart from each other with slits left between adjacent ones of the ball mounting regions.

According to another aspect of the present invention, there is provided a system module which includes at least one substrate each having an area on which the semiconductor chip is mounted and ball mounting regions extended from the predetermined area, and a plurality of metal balls mounted on said ball mounting regions of the at least one substrate. The ball mounting regions are spaced apart from each other with slits left between adjacent ones of the ball mounting regions.

According to still another aspect of the present invention, there is provided a substrate which includes a predetermined area and ball mounting regions extended from the predetermined area. The ball mounting regions are spaced apart from each other with slits left between adjacent ones of the ball mounting regions.

### BRIEF DESCRIPTION OF THE DRAWINGS

FIG. 1A is a plan view of a COB according to a conventional technique, and FIG. 1B is a sectional view showing that a surface mounting type stacked semiconductor package in which two COBs according to the conventional technique are stacked is mounted on a module substrate of an electric apparatus;

FIGS. 2A and 2B are a plan view and a sectional view of a first embodiment of the present invention;

FIG. 3 is a diagram showing a simulation result of a slit width and a strain amount; and

FIGS. 4A and 4B are a plan view and a sectional view of a second embodiment of the present Invention.

### DESCRIPTION OF THE PREFERRED EMBODIMENT

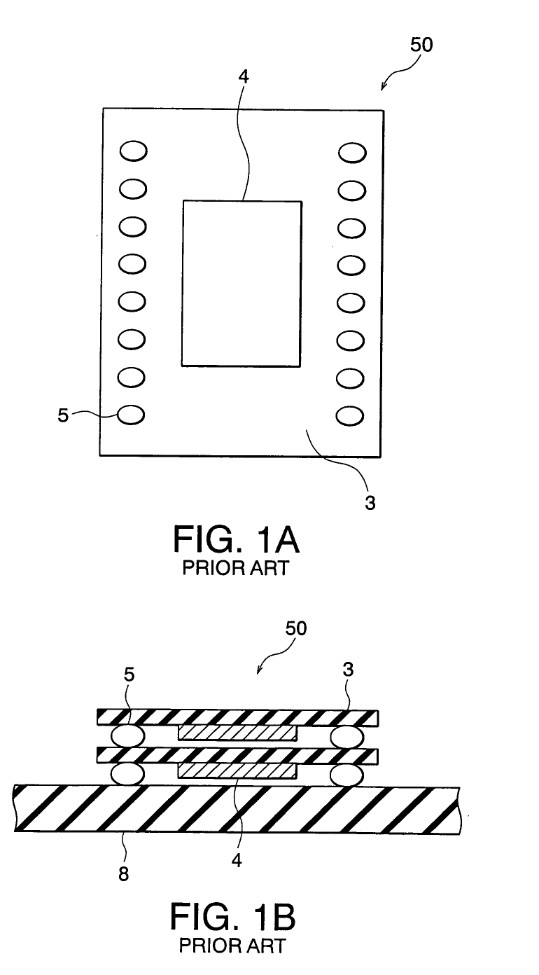

Prior to description of a preferable embodiment of the present invention, a semiconductor package and a system module according to a conventional technique will be described with reference to FIGS. 1A and 1B.

Referring to FIGS. 1A and 1B, a stacked semiconductor package 20 in which two COBs are stacked is mounted on a module substrate 8. In each COB, a semiconductor chip 4 and soldering balls 5 are mounted on a substrate 3 on which an inner wire (not shown) is laid. Two COBs are connected to each other via soldering balls of the upper COB, and are integrated as a stacked semiconductor package. The soldering balls of the lower COB are used in connecting an apparatus onto the module substrate.

Here, a substrate having a thermal expansion coefficient close to that of the semiconductor chip 4 (e.g., silicon) on which the substrate is to be mounted is used in the substrate 3, and an inexpensive epoxy glass substrate is used in the module substrate 8.

Therefore, a thermal expansion coefficient of the module substrate 8 is different from that of the package substrate 3, there is not any place where stresses generated in interfaces between the soldering balls 5 and the substrate are released, these stresses are largely applied to soldering bond, the soldering balls are strained, deformed, or cracked, and consequently there has been a problem in connection property, and long-time reliability.

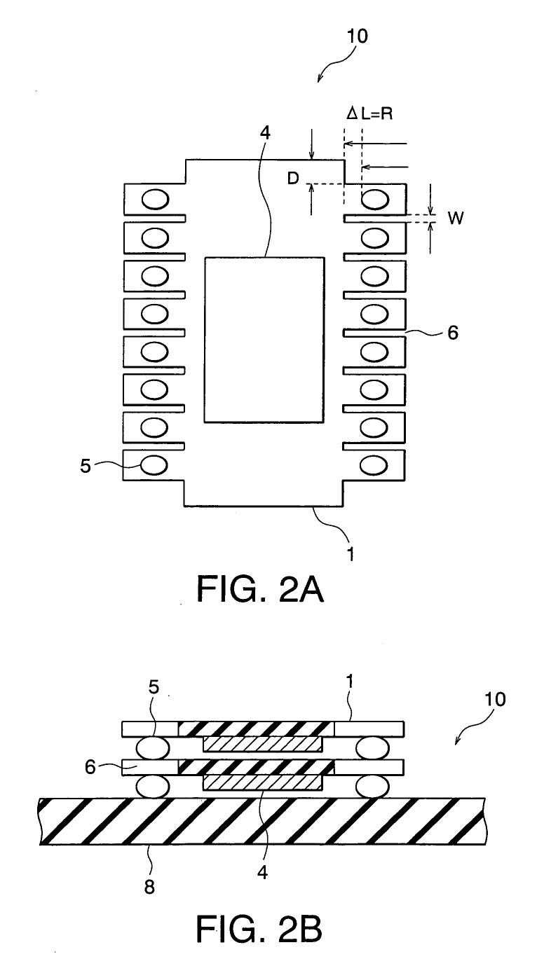

Then, embodiments of the present invention will be described with reference to FIGS. 2 to 4A and 4B.

### First Embodiment

Referring to FIG. 2A, a semiconductor package 10 has an inner wire (not shown) which is laid in the semiconductor package 10. The semiconductor package 10 is provided with a chip-on-board (COB) 11. The COB 11 includes a substrate 1. The substrate 1 includes a predetermined area 12 and ball mountaining regions 13 extended from the predetermined area 12. On the predetermined area 12, a semiconductor chip 4 is mounted. The ball mounting regions are spaced from each other with slits 6 left between adjacent ones of the boll mounting regions. On the ball mounting regions, soldering balls 5 are mounted.

The semiconductor chip may be a CPU or a DRAM chip. The substrate 1 may be epoxy glass, a synthetic resin such as a phenol resin, a ceramic plate, or a resin tape.

Referring to FIG. 2B, a system module includes a module substrate 8 and the stacked semiconductor package 10 on the module substrate 8. The stacked semiconductor package 10 has two COBs 11, 11 stacked.

In each COB 11, the semiconductor chip 4 is mounted on the substrate 1. A wire (not shown) is laid to a land portion around the substrate from the semiconductor chip 4. The chip 4 is connected to the soldering balls 5 of the land portion. Two COBs 11, 11 are stacked, and further mounted on the module substrate 8 of an apparatus. The two COBs 11, 11 are connected to each other via soldering balls of the upper COB, and accordingly two upper/lower COBs 11, 11 are integrated as a stacked semiconductor package. The package is connected to the module substrate 8 of the apparatus by the soldering balls of the lower COB, and the system module is formed.

The slits 6 are disposed in the substrate 1. The slits 6 are arranged in opposite-side regions including the soldering balls 5, and are also arranged in a vertical direction with respect to sides. Therefore, as to a periphery of the soldering ball 5, three sides including two sides cut from the substrate by the slit 6, and an original outer side of the substrate are cut from the substrate, and the periphery is connected to the substrate only by an inner side of the substrate. Therefore, a substrate portion including the soldering ball 5 is flexible, so that the stress generated in the interface between the soldering ball and the substrate can be released by a thermal expansion coefficient difference between the module substrate 8 and the package substrate 1. The stress applied to the soldering ball is weakened, and generation of strain, deformation, and crack of the soldering ball is prevented.

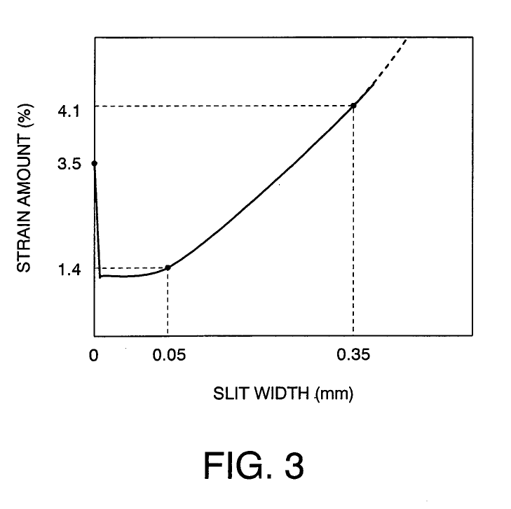

FIG. 3 shows a simulation result of a slit width and a soldering strain amount of the soldering ball. This simulation was executed, in a condition that a soldering ball pitch was set to 0.65 mm and a soldering ball diameter was set to 0.4 mm. When there is not any slit, the soldering strain amount is 3.5%. When the slit width is 0.05 mm, the soldering strain amount is 1.4%. When the slit width is 0.35 mm, the soldering strain amount is 4.1%. When the slits are disposed, the strain amount is improved. When the slit width is large, a result indicating that the soldering strain amount is deteriorated is obtained as compared with the case where there is not any slit.

When the slits are disposed, the substrate portion including the soldering ball is connected to the substrate main body only by one side, and becomes flexible. The stress applied to the soldering ball is softened, and the soldering strain amount is reduced. However, when the slit width increases, strength of the region connected to the substrate only by one side and including the soldering ball becomes insufficient. Furthermore, the substrate is twisted, and the strain amount applied to the soldering ball increases. That is, when the slit width is small, the substrate portion including the soldering ball has strength, and therefore there is less twist of the substrate. That is, when the substrate is deformed only in a flat face direction, the soldering strain amount is reduced. On the other hand, when the slit width is excessively large, the strength of the substrate portion including the soldering ball becomes insufficient. The substrate is deformed both in the flat face direction and a substrate vertical direction. Moreover, the substrate largely twists. As a result, the soldering strain amount is increased.

In general, the substrate 1 has one side of about 20 to 50 mm as a flat face and a thickness of about 1 to 3 mm or less. Since the soldering strain amount is generated based on a stress by a difference of the thermal expansion coefficient between the substrate 1 and the module substrate 8, the amount differs with the size and position of the substrate. The soldering strain amount in a side middle portion of the substrate is small, and the soldering strain amount in the end portion distant from the middle portion is large. Therefore, it is effective to dispose a slit in the end of the substrate whose soldering strain amount is large. However, when a distance (D) between the endmost soldering ball present in a substrate corner portion and a substrate outer side is as small as one pitch or less of the soldering ball, the cut side of the substrate imparts the same effect as that of the slit, and therefore the slit can be omitted.

Moreover, when two COBs 11, 11 are stacked to be the upper/lower COBs having the substrates formed of the same material and the thermal expansion coefficients equal to each other, shrinkages of the upper/lower COBs are equal. The soldering strain amount of the soldering ball is small. There may be slits or may not be any slits in the substrate of the upper COB.

The slit width (W) is preferably 0.3 mm or less with which the soldering strain amount is supposed to be equal or less as compared with a case where there is not any slit. As a lower limit, a micro slit may be formed, but the slit is more preferably 0.01 mm or more from productivity. A length of the slit is preferably in a range from the inside (middle) of a portion in which a soldering ball portion is disposed to a position for a soldering ball diameter (R) in a middle direction. That is, as shown, the length is preferably not less than a position where the soldering ball portion is disposed, and is within a position for a soldering ball diameter (R) in the middle direction.

Moreover, when the stacked semiconductor package 10 including the stacked COBs 11, 11 is mounted on the module substrate, the module substrate can be miniaturized. The whole system module can further be miniaturized. These are more effective in a case where especially a cellular phone or the like is required to be miniaturized, and are remarkable in a smaller system module. Furthermore, in a memory module on which eight or 36 same semiconductor memory chips are mounted, stacking is facilitated, the effect is very large, and a small-memory module can be constituted. The COBs in which the slits of the present invention are disposed are adopted, and further stored. Accordingly, the system module can be miniaturized, and the soldering strain amount is reduced. Therefore, a high-reliability system module is obtained. Herein, of course the soldering balls 5 may be melt to form soldering portions for connecting.

According to the present embodiment, the slits are arranged on the opposite sides of the soldering ball in a vertical direction with respect to the side in the outer peripheral side of the substrate of the package. The stress applied to the soldering ball is weakened, and the soldering balls can be prevented from being strained, deformed, or cracked. When these soldering strains are reduced, the surface mounting type semiconductor package having high reliability, low cost, and satisfactory electric characteristics such as low capacitance and low inductance is obtained. Furthermore, a system module on which these packages are mounted is obtained.

### Second Embodiment

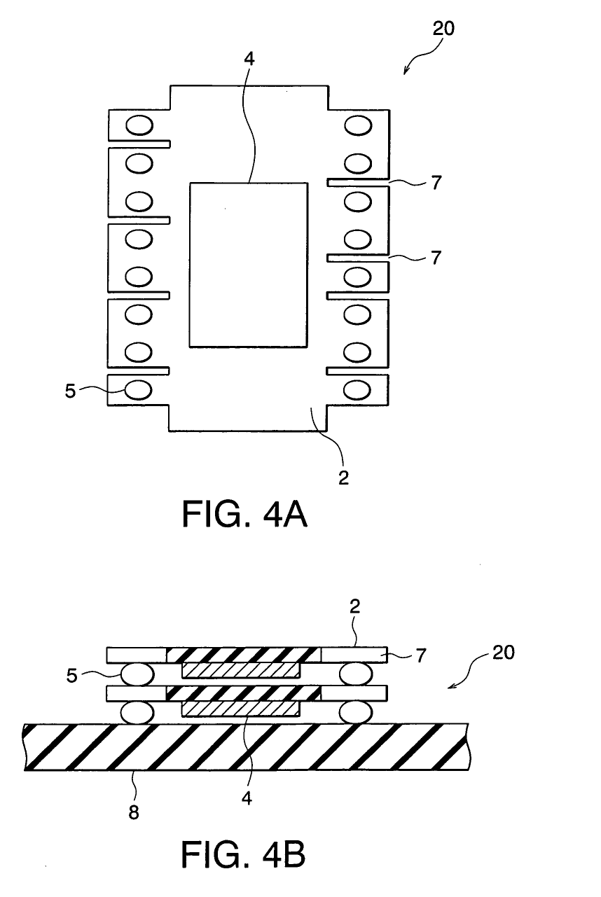

Referring to FIGS. 4A and 4B, a second embodiment of the present invention is different from the first embodiment only in positions where slits 7 are formed in a substrate 2 of a semiconductor package 20, other constituting elements are the same as those of the first embodiment, the elements are denoted with the same reference numerals, and the description is omitted.

The substrate 2 includes a predetermined area 12 and ball mountaining regions 13 extended from the predetermined area 12 and spaced apart from each other with slits 7 left between adjacent areas of the ball mounting regions 13. On the predetermined area 12, a semiconductor chip 4 is mounted. On the ball mounting regions, soldering balls 5 are mounted and the slits 7 are disposed in the first embodiment, one of the slits 6 is disposed with respect to one soldering ball 5. On the contrary, in the second embodiment, the slits 7 are disposed on opposite sides of a region of two adjacent soldering balls 5, 5 and in a vertical direction with respect to an outer side of the substrate 2.

Even in a case where two adjacent soldering balls 5, 5 are regarded one group, and the slits 7 are disposed on the opposite sides of the region including two soldering balls 5, 5, the size of the substrate 2 cut off by the slits 7 simply becomes large, and an effect similar to that of the slit 6 of the first embodiment is obtained.

Even in a case where two adjacent soldering balls 5, 5 are regarded as one group, stresses generated in interfaces between the soldering balls 5, 5 and the substrate 2 can be released by a thermal expansion coefficient difference between the module substrate 8 and the package substrate 2. In addition, the stresses applied to the soldering balls 5, 5 are weakened. Furthermore, the soldering balls 5, 5 can be prevented from being strained, deformed, and cracked. Since the slits 7 are disposed, the substrate portion including the soldering ball 5 becomes flexible. In addition, the stress applied to the soldering ball 5 is softened. Furthermore, the soldering strain amount decreases. Here, a shape (width, length) of the slit 7 is the same as that of the slit 6 of the first embodiment.

Thus, the slits 7 do not have to be formed in all the soldering balls 5, 5. Slit intervals can be variously set in a range in which the stress generated in the interface between the soldering ball 5 and the substrate 2 can be released by the thermal expansion coefficient difference between the module substrate 8 and the package substrate 2, and the stress applied to the soldering ball 5, 5 is weakened. However, in a case where the number of soldering balls 5 regarded as one group is increased, the size cut by the slit becomes excessively large, the side connected to the substrate 2 becomes solid, and flexibility of the cut/separated region is eliminated. Therefore, the number (N) of soldering balls regarded as one group is preferably five or less.

According to the present embodiment, the slits 7 are disposed on opposite sides of two soldering balls 5, 5 in the vertical direction with respect to the side in the outer peripheral side of the substrate of the package 20. Accordingly, a semiconductor package and a system module are obtained in which the stresses applied to the soldering ball are weakened, and the soldering balls are prevented from being strained, deformed, and cracked.

Moreover, according to the present invention, slits 6, 7 are disposed on opposite sides of one or a plurality of soldering balls 5, 5 in a vertical direction with respect to the side in the outer peripheral side of the substrate 1, 2 of the package 10, 20. Accordingly, the semiconductor package 10, 20 and the system module are obtained in which the stresses applied to the soldering balls 5, 5 are weakened, and the soldering balls 5, 5 are prevented from being strained, deformed, and cracked.

In the present invention, when the slits 6, 7 are disposed on the opposite sides of the soldering ball 5 or two soldering balls 5, 5 of the package substrate 1, 2, the stresses applied to the soldering balls 5, 5 are weakened, and the soldering balls 5, 5 can be prevented from being strained, deformed, and cracked. When these soldering strains are reduced, a small-sized surface mounting type semiconductor package 10, 20 can be obtained having high reliability, low cost, and satisfactory electric characteristics such as low capacitance and low inductance. Moreover, a small-sized system module including these semiconductor packages mounted thereon and having high reliability, low cost, and satisfactory electric characteristics can be obtained.

The present invention has been concretely described above in accordance with the embodiments, but the present invention is not limited to the embodiments, and can be variously changed without departing from the scope. For example, the COB 11 has been described as the embodiment of the semiconductor package, but μBGA or FBGA may be used. The substrates 1, 2 may be tapes. The soldering balls may be gold balls, and can be variously changed. Especially in a case where the gold balls are used, solder plating or the like is applied to the land or pad portion, a solder plating film is disposed around the gold ball, or a solder paste is attached to thereby solder and connect the portions by reflow or the like.

1. A semiconductor package having a semiconductor chip mounted thereon, said semiconductor package comprising:
a substrate having an area on which the semiconductor chip is mounted and ball mounting regions extended from the predetermined area; and
a plurality of metal balls mounted on said ball mounting regions of the substrate;
said ball mounting regions being spaced apart from each other with slits left between adjacent ones of the ball mounting regions.

2. The semiconductor package according to claim 1, wherein a width of the slit is in a range of 0.01 to 0.3 mm.

3. The semiconductor package according to claim 1, wherein the metal balls are soldering balls.

4. The semiconductor package according to claim 3, wherein
the slits are extended from an outer side of the substrate inwardly to define the ball mounting regions.

5. The semiconductor package according to claim 1, wherein said predetermined area is mounted by a semiconductor chip.

6. The semiconductor package according to claim 1, wherein each of inner ends each of the slits is placed in a position that is inner than a ball position in which a soldering ball is disposed and that is outer than a position a diameter of the solder ball away from the ball position.

7. A system module comprising:
at least one substrate each having an area on which the semiconductor chip is mounted and ball mounting regions extended from the predetermined area; and
a plurality of metal balls mounted on said ball mounting regions of the at least one substrate; and
said ball mounting regions being spaced apart from each other with slits left between adjacent ones of the ball mounting regions.

8. The system module according to claim 7, wherein a width of the slit is in a range of 0.01 to 0.3 mm.

9. The system module according to claim 7, wherein the metal balls are soldering balls.

10. The system module according to claim 9, wherein the slits are extended from an outer side of the substrate inwardly to define the ball mounting regions.

11. The system module according to claim 7, wherein said predetermined area is mounted by a semiconductor chip.

12. The system module according to claim 7, wherein each of inner ends each of the slits is placed in a position that is inner than a ball position in which a soldering ball is disposed and that is outer than a position a diameter of the solder ball away from the ball position.

13. A substrate comprising a predetermined area and ball mounting regions extended from the predetermined area, said ball mounting regions being spaced apart from each other with slits left between adjacent ones of the ball mounting regions.

14. The substrate according to claim 13, wherein each of said slits has one opened end in a longitudinal direction.

15. The substrate according to claim 13, wherein a width of the slit is in a range of 0.01 to 0.3 mm.

16. The substrate according to claim 13, wherein the metal balls are soldering balls.

17. The substrate according to claim 13, wherein the slits are extended from an outer side of the substrate inwardly to define the ball mounting regions.

18. The substrate according to claim 13, wherein said predetermined area is mounted by a semiconductor chip.

19. The substrate according to claim 13, wherein each of inner ends of the slits is placed in a position that is inner than a ball position in which a soldering ball is disposed and that is outer than a position inwardly a diameter of the solder ball away from the ball position.
